(19) United States
(12) Patent Application Publication
(10) Pub. No.: US 2013/0208912 A1
(43) Pub. Date: Aug. 15, 2013

(54) SIMULATION OF ENGINE SOUNDS IN SILENT VEHICLES

(71) Applicant: Kurt O. Wiederwohl, Graz (AT)

(72) Inventor: Kurt O. Wiederwohl, Graz (AT)

(73) Assignee: BDP SICHERHEITSTECHNOLOGIEN GMBH, Graz (AT)

(21) Appl. No.: 13/641,251

(22) PCT Filed: Mar. 28, 2011
(86) PCT No.: PCT/EP11/54683

§ 371 Date: Dec. 21, 2012

(30) Foreign Application Priority Data
Apr. 16, 2010 (AT) A 625/2010

(51) Int. Cl. H03G 3/20

(52) U.S. Cl. CPC H03G 3/20
USPC 381/86

(57) ABSTRACT

The invention relates to a vehicle (1) having an alternative engine (2) and having at least one first loudspeaker (7) for outputting a sound to the surroundings of the vehicle (1), wherein a microphone (3, 4, 5) is provided in the engine space of the vehicle (1) in order to pick up the engine sounds of the engine (2) and that amplifier means (6) are provided in order to amplify the picked-up engine sounds and wherein the first loudspeaker (7) is provided in the engine space in order to re-output the picked-up engine sounds in amplified form directly in the engine space.

The invention relates to a vehicle having an alternative engine and having at least one first loudspeaker for outputting a sound to the surroundings of the vehicle.

Document EP 1 562 177 A2 discloses a sound generator for an electric car which has a loudspeaker for outputting sounds, tones and tunes. The engine of electric cars is relatively silent in comparison to a gasoline engine or a diesel engine. In recent years, this has lead to a number of accidents involving pedestrians or cyclists who have relied upon their sense of hearing and have failed to notice an approaching electric car. The known sound generator is formed by a computer by means of which predetermined sounds, tones and tunes are stored. A plurality of sensors are connected to the computer which, for example, measure the vehicle's speed and other technical data of the vehicle, but also the heart rate or eye movements of the driver. In addition, the surroundings of the vehicle are monitored by radar in order to detect pedestrians, for example. The computer executes a navigation software in order to include in its calculations pedestrian crossings and other relevant events on or beside the road. Based on these calculations, one of the sounds, tones or tunes stored by means of the computer is output via several loudspeakers in order to inform pedestrians and other road users about the silently approaching electric car.

In addition, a microphone is connected to the sound generator by means of which ambient sounds outside of the vehicle are picked up. Depending on the detected loudness level of the ambient sounds, the loudness level of the stored sounds, tones or tunes output by the loudspeakers is regulated in the known sound generator.

The object on which the invention is based is to provide a simple and inexpensive possibility of rendering vehicles having an alternative and therefore silent engine audible and thus noticeable for other road users. In the aforesaid vehicle, this object is achieved in that a microphone is provided in the engine space of the vehicle in order to pick up the engine sounds of the engine and amplifier means are provided in order to amplify the picked-up engine sounds and wherein the first loudspeaker is provided in the engine space in order to re-output the picked-up engine sounds in amplified form directly in the engine space.

Through this, the advantage is obtained that engine sounds picked up in the engine space by a simple microphone are directly re-output in amplified form into the engine space by a conventional amplifier. The outputting of the amplified engine sounds in the engine space gives a pedestrian or cyclist precisely the impression which also an approaching conventional vehicle having a gasoline or diesel engine would produce. As a result, a device for a better perception of the vehicle, which is particularly inexpensive and reliable throughout the vehicle's lifetime, is obtained. Further sensors and loudspeakers for picking up and outputting, for example, the rolling sounds of the tyres in order to give other persons the impression of an approaching vehicle are not necessary since they occur naturally and blend with the engine sound into the vehicle sound.

It has turned out to be advantageous to attach the first loudspeaker to the inside of the bonnet. In a way, the bonnet forms a large membrane which outputs the engine sounds in the engine space to the surroundings of the vehicle. By providing the loudspeaker at the bonnet, engine sounds are produced a pedestrian or cyclist is familiar with from a conventional vehicle. Furthermore, as a result of this, the risk of feedbacks of the sound output by the first loudspeaker into the microphone is very small.

In order to give the driver of the vehicle a better feedback about the current operating state (engine speed, load, . . . ) of the electric engine, it has turned out to be advantageous to provide a second loudspeaker in the passenger compartment so that the electric engine will be heard better also in the passenger compartment. Furthermore, it is advantageous if loudness level adjustment means are provided by means of which the loudness level of the engine sounds output by the first and/or the second loudspeaker is adjustable.

In order to guarantee a certain minimum loudness level of all electric cars licensed for traffic, it may be advantageous if the loudness level adjustment means, in particular with regard to the loudness level of the first loudspeaker in the engine space, can be adjusted only by the car manufacturer. In future, a minimum loudness level for electric vehicles might be required by law which is adjusted by the car manufacturer once and is not alterable in any way afterwards.

If the user listens, for example, to classical music in the car or speaks over the handsfree equipment, it may be advantageous if the loudspeakers for outputting the amplified engine sound are designed so that they can be switched off. However, it is particularly advantageous to allow only the second loudspeaker in the passenger compartment to be switched off in order to prevent the electric car from running too silently and a new accident risk from emerging.

In addition to the one microphone, a second and also further microphones can be attached in different positions in the engine space for picking up various aspects of the engine sound.

Thus, a microphone could be provided, for example, directly beside a gear and another one beside a cam belt or an electromotive brake of the electric engine. A person skilled in the art of sound design is able to find suitable positions in different electric engines and to appropriately mix the aspects of the engine sound picked up by the respective microphones in the amplifier means.

Furthermore, it may be advantageous to provide certain sound protection means such as acoustic panels or insulating boards in order to shield off the sound output by the first loudspeaker. Likewise, it may be advantageous to provide sound guide means in order to guide virtually exclusively the sound of the selected component in the electric engine to the microphone and to pick it up therewith.

Further advantageous embodiments of the vehicle according to the invention are illustrated below in further detail on the basis of the figures.

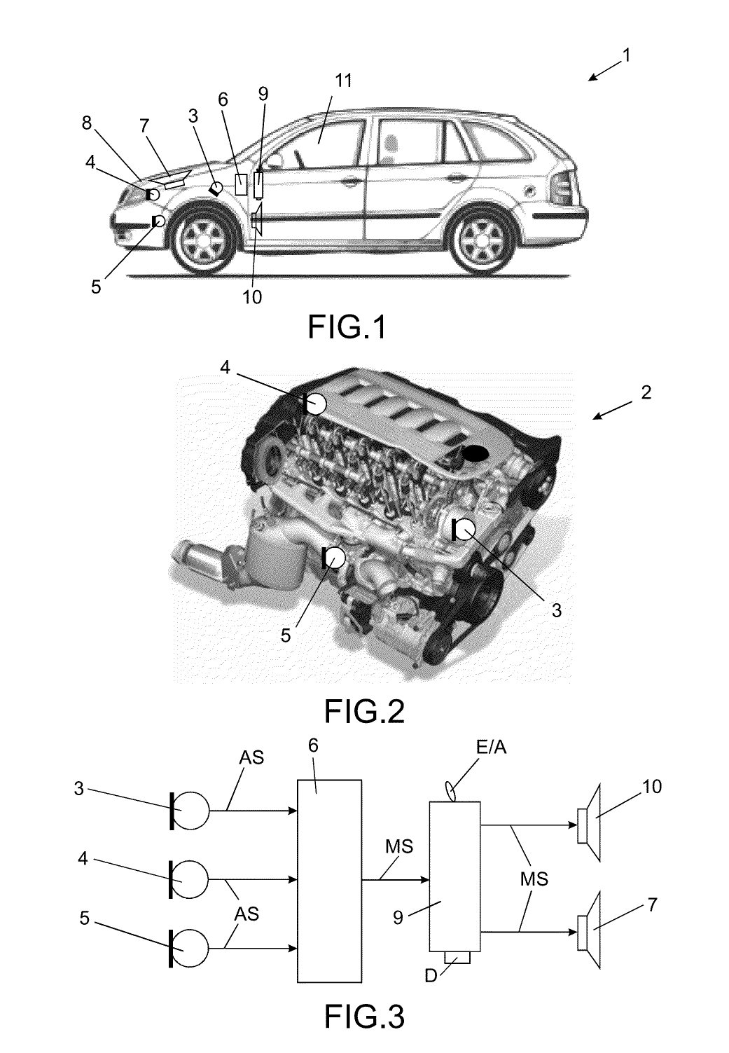

FIG. 1 shows a side view of a vehicle comprising a hybrid engine.

FIG. 2 shows the hybrid engine of the vehicle according to FIG. 1.

FIG. 3 shows a circuit diagram of the device for producing amplified engine sounds in the vehicle according to FIG. 1.

FIG. 1 shows a vehicle 1 having an alternative engine illustrated in FIG. 2, wherein the alternative engine is formed by a hybrid engine 2. The hybrid engine 2 comprises both a gasoline unit and an electric unit. At slow speeds without any particular power requirement, the electric unit is used for powering the vehicle 1 in an electric operating mode. In contrast, at higher speeds or, for example, on mountain roads with steep gradients, the gasoline unit is used for powering the vehicle 1 in a gasoline operating mode. If the gasoline unit of the hybrid engine 2 is switched on, the vehicle 1 outputs a normal engine sound to which road users have become accustomed throughout many decades. However, as soon as the gasoline unit is switched off and the vehicle 1 is powered via the electric unit, only the relatively muted engine sounds of the electric unit are output by the vehicle 1.

For this reason, the vehicle 1 comprises three microphones 3, 4 and 5 which are attached in different positions in the engine space in order to pick up various aspects of the engine sound. Furthermore, the vehicle 1 comprises amplifier means 6 which are formed by a commercially available audio amplifier and to which the audio signal AS output by the three microphones 3, 4 and 5 is delivered. The amplifier means 6 are designed for amplifying the audio signals AS, wherein a particular sound design of the engine sound is determined by the car manufacturer by mixing the audio signals AS received by the three microphones 3, 4 and 5 and amplified to varying degrees into the engine sound signal MS output by the amplifier means 6.

Furthermore, the vehicle 1 comprises a first loudspeaker 7 which is attached to the inside of the bonnet 8 of the vehicle 1. The engine sound signal MS is output by the amplifier means 6 via loudness level adjustment means 9 to the first loudspeaker 7. The sound output by the first loudspeaker 7 directly hits the bonnet 8 which, in a way, acts like a large membrane and outputs the amplified engine sound to the surroundings of the vehicle 1. Since, during the operation of the vehicle 1, the bonnet 8 outputs the engine sounds of the gasoline unit to the surroundings of the vehicle 1 in a comparable way (e.g., resonance frequency, sound pressure), the vehicle 1 has a comparable sound in both operating modes and is easily perceptible.

By directly picking up the engine sound of the electric unit and outputting the amplified engine sound via the first loudspeaker 1, the advantage is obtained that the output engine sound will always match the current operating state (e.g., engine speed, load of the electric unit, . . . ) of the electric unit. If a stored or artificially produced sound is output by the first loudspeaker 1, the vehicle would have to be provided with a plurality of sensors and an expensive computer in order to reliably ensure this matching between the output engine sound and the operating state.

Furthermore, the vehicle 1 now comprises a second loudspeaker 10 to which the engine sound signal MS is likewise delivered from the amplifier means 6 via the loudness level adjustment means 9 and which is located in the vehicle's 1 passenger compartment 11. The user of the vehicle 1 is able to turn on or off the second loudspeaker 10 by means of an on/off switch E/A on the loudness level adjustment means 9 and to regulate the loudness level output by the loudspeaker 10 by means of a variable controller D of the loudness level adjustment means 9. Through this, the advantage is obtained that drivers of the vehicle 1 who wish to receive an acoustic feedback about the operating state of the electric unit can turn on the engine sounds output by the second loudspeaker 10 at an appropriate loudness level. The loudspeaker 10 thus enables a physical connection of the driver to the respective driving condition of the vehicle 1, as a result of which the accident risk is minimized. Because of this, the driver can drive the vehicle in a significantly better way. However, if the driver wants to have silence in the passenger compartment 11, for example, for a telephone call, he or she can turn off the second loudspeaker 10 by means of the on/off switch E/A.

However, for safety reasons, it may be provided that the loudspeaker 10 cannot be turned off completely, i.e., only to a certain extent, so that the driver will, in any case, receive an appropriate feedback from the engine. Furthermore, it may be provided that the reduction of the loudness level of the loudspeaker 10 or the switching-off of the loudspeaker 10 is possible only for a certain period of time after which the loudspeaker 10 is automatically reset to a given loudness level. In this way, it is made sure that a driver does not forget after a telephone call to reset the loudspeaker 10 to a loudness level which reduces the accident risk.

In FIG. 3, a circuit diagram of the device for producing amplified engine sounds in the vehicle 1 according to FIG. 1 is depicted. The number of three microphones 3, 4 and 5 and of two loudspeakers 7 and 10 is to be understood only as an example, since an arbitrary larger or smaller number of microphones and loudspeakers can be provided depending on the vehicle type and the design of the electric engine.

It is assumed that the legal requirements of the country in which the vehicle 1 is to be registered will define a minimum loudness level for vehicles having an electric engine. For this reason, said minimum loudness level has been adjusted by the car manufacturer in the loudness level adjustment means 9 for the first loudspeaker 7 in the engine space 8, which is why the first loudspeaker 7 can never be turned off completely by the user. Hereby, it is made sure that the vehicle 1 in the electric operating mode will always be heard well by other road users. However, the loudness level of the first loudspeaker 7 can either be regulated automatically depending on the ambient sounds or can be chosen manually and changed to a certain extent according to the user's wishes by means of the loudness level adjustment means 9.

In order to prevent that the amplified engine sound output by the first loudspeaker 7 is directly picked up again as a feedback by the microphones 3, 4 and 5 and amplified further, sound protection means as well as sound guide means are provided. The sound protection means are formed from a sound-absorbing material, as it is common, for example, in vehicles for acoustically shielding off the engine space from the passenger compartment. The sound protection means are attached in close proximity to the microphones 3, 4 and 5 in order to interrupt the direct path of the sound from the first loudspeaker 7 to the microphones 3, 4 and 5. In this way, only a sound of the first loudspeaker 7 which has been reflected one or several times and, hence, is already very muted can reach one of the microphones 3, 4 and 5, whereby feedbacks are virtually impossible.

In addition, sound guide means leading to the microphone from the component of the electric unit the sound of which is to be picked up by the microphone are provided. Such sound guide means may be formed, for example, from a bent plastic pipe or other comparable means which are known in the field of acoustics.

Particularly advantageously, switching means are to be provided in a vehicle 1 having a hybrid engine 2, which switching means switch off the outputting of the amplified engine sounds by the loudspeakers 7 and 10 if the vehicle 1 is powered in the gasoline operating mode by the gasoline unit of the hybrid engine 2, and switch on the outputting of the amplified engine sounds if the vehicle 1 is powered in the electric operating mode by the electric unit of the hybrid engine 2. As a result, it is achieved that the vehicle 1 can be perceived equally well by other road users in both operating modes and the accident risk caused by not hearing the vehicle 1 in the electric operation is thereby substantially reduced.

It may be mentioned that by the term “alternative engine” any drive unit for a vehicle is to be understood which is not formed by a gasoline or diesel engine with the currently common engine sounds. Alternative engines are thus, for example, electric engines, gas engines or hydrogen engines. In case particularly silent gasoline or diesel engines the engine sounds of which are too muted for general traffic safety will be developed in future, the measures according to the invention can advantageously be provided also in such engines.

It may be mentioned that vehicles are understood to be not only cars but also electric bikes, buggies or other means suitable for transportation.

1.-11. (canceled)

12. A vehicle having an alternative engine, comprising:
at least one first loudspeaker for outputting a sound to a surroundings of the vehicle;
a microphone in an engine space of the vehicle in order to pick up engine sounds of the engine;
amplifier means in order to amplify the picked-up engine sounds, wherein the first loudspeaker is provided in the engine space in order to re-output the picked-up engine sounds in amplified form directly in the engine space;
a second loudspeaker provided in a passenger compartment which outputs the engine sounds amplified by the amplifier means to the passenger compartment; and
a loudness level adjustment means provided for selectively adjusting the loudness level of the engine sounds output by the first and/or the second loudspeaker, wherein the loudness level adjustment means is adjustable by a user of the vehicle only to a certain extent and that the outputting of the amplified engine sounds in the engine space at least via the first loudspeaker cannot be switched off by the user of the vehicle.

13. The vehicle according to claim 12, wherein the first loudspeaker is attached to the inside of the hood.

14. The vehicle (1) according to claim 12, wherein, according to respective approval requirements, the loudness level adjustment means is not adjustable in any way once they have been adjusted by a vehicle manufacturer.

15. The vehicle according to claim 12, wherein at least two microphones are provided in different positions in the engine space in order to selectively pick up sounds in the engine space and output them via at least the first loudspeaker after they have been mixed at a different loudness level.

16. The vehicle according to claim 12, further comprising, microphone sound protection means provided for shielding off the engine sound output by the first loudspeaker and/or sound guide means for guiding the engine sound to be picked up by the microphone.

17. The vehicle according to claim 12, wherein the alternative engine is formed by an electric engine.

18. The vehicle according to claim 12, wherein the alternative engine is formed by a hybrid engine and switching means are provided which switch off the outputting of the amplified engine sounds if the vehicle is powered by a gasoline or diesel unit of the hybrid engine, respectively, and which switch on the outputting of the amplified engine sounds if the vehicle is powered by an electric unit of the hybrid engine.

19. The vehicle according to claim 13, wherein the alternative engine is formed by a hybrid engine and switching means are provided which switch off the outputting of the amplified engine sounds if the vehicle is powered by a gasoline or diesel unit of the hybrid engine, respectively, and which switch on the outputting of the amplified engine sounds if the vehicle is powered by an electric unit of the hybrid engine.

20. The vehicle according to claim 13, wherein, according to respective approval requirements, the loudness level adjustment means is not adjustable in any way once they have been adjusted by a vehicle manufacturer.

21. The vehicle according to claim 13, wherein at least two microphones are provided in different positions in the engine space in order to selectively pick up sounds in the engine space and output them via at least the first loudspeaker after they have been mixed at a different loudness level.

22. The vehicle according to claim 14, wherein at least two microphones are provided in different positions in the engine space in order to selectively pick up sounds in the engine space and output them via at least the first loudspeaker after they have been mixed at a different loudness level.

23. The vehicle according to claim 13, further comprising microphone sound protection means provided for shielding off the engine sound output by the first loudspeaker and/or sound guide means for guiding the engine sound to be picked up by the microphone.

24. The vehicle according to claim 14, further comprising microphone sound protection means provided for shielding off the engine sound output by the first loudspeaker and/or sound guide means for guiding the engine sound to be picked up by the microphone.

25. The vehicle according to claim 15, further comprising microphone sound protection means provided for shielding off the engine sound output by the first loudspeaker and/or sound guide means for guiding the engine sound to be picked up by the microphone.

26. The vehicle according to claim 13, wherein the alternative engine is formed by an electric engine.

27. The vehicle according to claim 14, wherein the alternative engine is formed by an electric engine.

28. The vehicle according to claim 15, wherein the alternative engine is formed by an electric engine.

29. The vehicle according to claim 13, wherein the alternative engine is formed by a hybrid engine and switching means are provided which switch off the outputting of the amplified engine sounds if the vehicle is powered by a gasoline or diesel unit of the hybrid engine, respectively, and which switch on the outputting of the amplified engine sounds if the vehicle is powered by an electric unit of the hybrid engine.

30. The vehicle according to claim 14, wherein the alternative engine is formed by a hybrid engine and switching means are provided which switch off the outputting of the amplified engine sounds if the vehicle is powered by a gasoline or diesel unit of the hybrid engine, respectively, and which switch on the outputting of the amplified engine sounds if the vehicle is powered by an electric unit of the hybrid engine.

31. The vehicle according to claim 15, wherein the alternative engine is formed by a hybrid engine and switching means are provided which switch off the outputting of the amplified engine sounds if the vehicle is powered by a gasoline or diesel unit of the hybrid engine, respectively, and which switch on the outputting of the amplified engine sounds if the vehicle is powered by an electric unit of the hybrid engine.
